(19) United States
(12) Patent Application Publication
(10) Pub. No.: US 2025/0127009 A1
(43) Pub. Date: Apr. 17, 2025

(54) DISPLAY DEVICE

(71) Applicant: LG Display Co., Ltd., Seoul (KR)

(72) Inventors: Suk Choi, Hwaseong-si (KR); Mose Lee, Bucheon-si (KR); MooJin Kwak, Incheon (KR); Sungjin Park, Seoul (KR)

(73) Assignee: LG Display Co., Ltd., Seoul (KR)

(21) Appl. No.: 18/913,536

(22) Filed: Oct. 11, 2024

(30) Foreign Application Priority Data
Oct. 13, 2023 (KR) 10-2023-0137062

(51) Int. Cl. H10K 59/50; H10K 59/80; H10K 102/00

(52) U.S. Cl. CPC H10K 59/50; H10K 59/8792; H10K 59/8794; H10K 2102/351

(57) ABSTRACT

An organic light emitting display is disclosed. The organic light emitting display includes a glass substrate, an organic light emitting element on the glass substrate, and a phase retardation layer disposed under the glass substrate. Accordingly, a crack created on the glass substrate can be readily detected, ensuring improvement in the durability and reliability of the display device.

### CROSS-REFERENCE TO RELATED APPLICATION

This application claims the priority of Korean Patent Application No. 10-2023-0137062, filed on Oct. 13, 2023, in the Korean Intellectual Property Office, the disclosure of which is incorporated herein by reference.

### BACKGROUND

### Field

The present disclosure relates to an organic light emitting display device and, more particularly, to an organic light emitting display device minimizing a crack.

### Description of the Related Art

Organic light emitting display (OLED) devices, unlike liquid crystal display (LCD) devices provided with a backlight, do not need a separate light source. Accordingly, the OLED devices can secure lightweight and slimness, advantages in manufacturing, and less power consumption based on low-voltage driving. Above all, an organic light emitting display device comprises a self-emitting element and layers respectively formed into a thin organic film, thereby securing flexibility and elasticity greater than those of other display devices and being embodied as a flexible display device.

Ordinarily, an organic light emitting display device uses an organic light emitting element that emits light in the case where an electron and a hole respectively from a cathode for injecting an electron and an anode for injecting a hole are injected into a light emitting layer, and an exciton in which the injected electron and the injected hole are coupled falls into a ground state from an excitation state.

In recent years, a display device where an organic light emitting element and the like are formed on a flexible substrate made of a flexible material such as plastics and the like have drawn attention, but a glass substrate is still used since the glass substrate ensures ease of manufacturing and stiffness.

In particular, when it comes to a display device where an organic light emitting element is formed on a thin film glass substrate, research has been actively conducted into technologies for preventing and detecting a crack that may be created on the glass substrate.

### SUMMARY

One objective of the present disclosure is to provide an organic light emitting display device that can readily detect a minute crack of a glass substrate on which an organic light emitting element is disposed.

Another objective of the present disclosure is to provide an organic light emitting display device that can readily detect a crack created even in a non-display area of the glass substrate.

Yet another objective of the present disclosure is to provide an organic light emitting display device that can prevent a crack, ensuring improvement in durability and reliability.

Objects of the present disclosure are not limited to the above-mentioned objects, and other objects, which are not mentioned above, can be clearly understood by those skilled in the art from the following descriptions.

To achieve these objects and other advantages of the present disclosure, as embodied and broadly described herein, an organic light emitting display device of one embodiment may include a glass substrate, an organic light emitting element on the glass substrate, and a phase retardation layer disposed under the glass substrate. Accordingly, a crack created on the glass substrate can be readily detected, ensuring improvement in the durability and reliability of the display device.

Other detailed matters of the example embodiments are included in the detailed description and the drawings.

According to example embodiments of the present disclosure, a crack created even on the outer side of the glass substrate can be readily detected.

According to example embodiments of the present disclosure, a minute crack created on the glass substrate can be readily detected.

According to example embodiments of the present disclosure, a crack on the glass substrate can be prevented, ensuring improvement in the durability and reliability of the display device.

The advantages and effects according to the present disclosure are not limited to those described above, and additional advantages and effects are included in or may be obtained from the present disclosure.

Additional features and aspects of the disclosure will be set forth in the description that follows and in part will become apparent from the description or may be learned by practice of the inventive concepts provided herein. Other features and aspects of the inventive concepts may be realized and attained by the structure particularly pointed out in, or derivable from, the written description, claims hereof, and the appended drawings.

It is to be understood that both the foregoing general description and the following detailed description of the present disclosure are by way of example and are intended to provide further explanation of the disclosures as claimed.

### BRIEF DESCRIPTION OF THE DRAWINGS

The accompanying drawings, which are included to provide a further understanding of the disclosure and are incorporated in and constitute a part of this application, illustrate example embodiments of the disclosure and together with the description serve to explain the principles of the disclosure. In the drawings:

FIG. 1 is a schematic diagram of an organic light emitting display device according to an example embodiment of the present disclosure;

FIG. 2 is a cross-sectional view along I-I′ of FIG. 1;

FIG. 3 is a cross-sectional view along II-II′ of FIG. 1;

FIG. 4 is a cross-sectional view of on organic light emitting display device of another example embodiment;

FIG. 5 is a cross-sectional view of an organic light emitting display device of another example embodiment;

FIG. 6 is a cross-sectional view of an organic light emitting display device of yet another example embodiment; and

FIG. 7 is a schematic view of a process of detecting a crack of a glass substrate in the organic light emitting display device of an example embodiment of the present disclosure.

### DETAILED DESCRIPTION

Advantages and features of the present disclosure and methods of achieving them will become apparent with reference to the example embodiments described below in detail in conjunction with the accompanying drawings. The present disclosure may, however, be embodied in different forms and should not be construed as limited to the example embodiments set forth herein. Rather, these example embodiments are provided so that this disclosure will be thorough and complete and will fully convey the scope of the present disclosure to those skilled in the art.

The shapes, sizes, ratios, angles, numbers, and the like, illustrated in the accompanying drawings for describing various example embodiments of the present disclosure, are merely given by way of example. Therefore, the present disclosure is not limited to such illustrated details in the drawings.

In the following description, where a detailed description of a relevant known function or configuration may unnecessarily obscure aspects of the present disclosure, a detailed description of such a known function or configuration may be omitted or be briefly discussed.

Where a term like “include,” “have,” or “consist of” is used, one or more other elements may be added unless the term is used with a more limiting term, such as “only” or the like. An element described in a singular form may include a plurality of elements, and vice versa, unless the context clearly indicates otherwise.

In construing an element, the element should be construed as including an error or tolerance range even where no explicit description of such an error or tolerance range is provided.

Where a positional relationship between two elements is described with such a term as “on,” “above,” “below,” “next,” or the like, one or more other elements may be located between the two elements unless the term is used with a more limiting term, such as “immediate(ly)” or “direct(ly).”

For example, where a first element is described as being positioned “on” a second element, the first element may be positioned above and contact the second element or may merely be above the second element with one or more additional elements disposed between the first and second elements.

Although terms “first,” “second,” and the like may be used herein to describe various elements, these elements should not be interpreted to be limited by these terms as they are not used to define a particular essence, order, sequence, precedence, or number of such elements. These terms are used only to refer to one element separately from another. For example, a first element could be termed a second element, and a second element could similarly be termed a first element, without departing from the scope of the present disclosure.

Like reference numerals generally denote like elements throughout the specification, unless otherwise specified.

A size and a thickness of each component illustrated in the drawing are illustrated for convenience of description, and the present disclosure is not limited to the size and the thickness of the component illustrated.

Features of various embodiments of the present disclosure may be partially or wholly coupled to or combined with each other, and may be operated, linked, or driven together in various ways as those skilled in the art can sufficiently understand. The embodiments of the present disclosure may be carried out independently from each other or may be carried out together in association with each other.

Hereinafter, an organic light display device according to example embodiments of the present disclosure will be described in detail with reference to accompanying drawings.

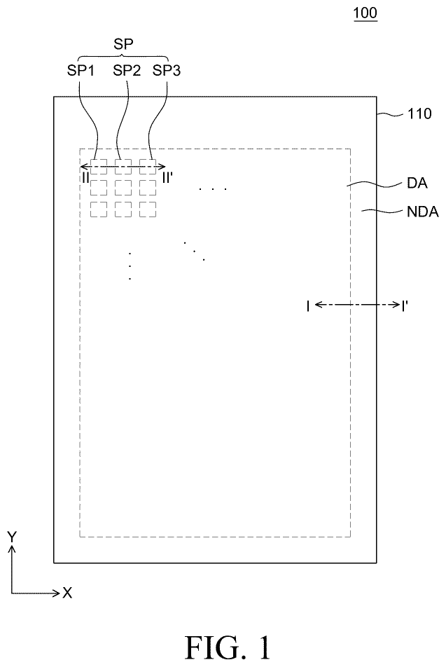

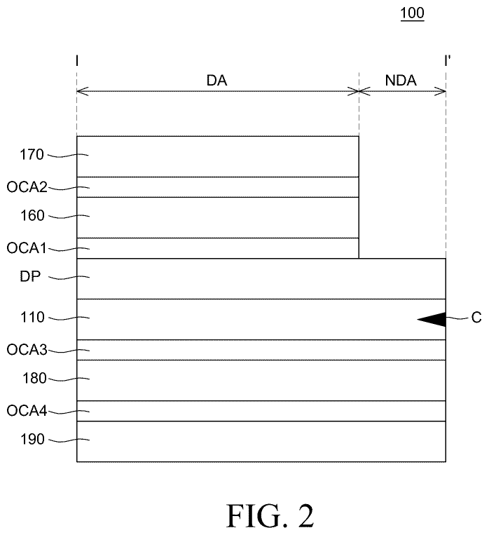

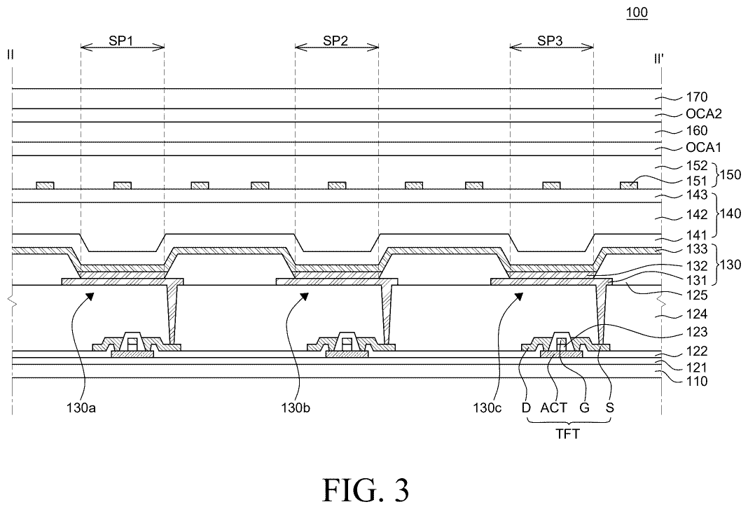

FIGS. 1-3 are views for describing an organic light emitting display device of one embodiment. FIG. 1 is a schematic diagram of an organic light emitting display device of one embodiment. FIG. 2 is a cross-sectional view along I-I′ of FIG. 1. FIG. 3 is a cross-sectional view along II-II′ of FIG. 1.

As shown in FIGS. 1-3, an organic light emitting display device 100 of one embodiment comprises a glass substrate 110, a thin film transistor TFT, an organic light emitting element 130, an encapsulation layer 140, a touch sensor part 150, a polarization layer 160, a cover glass 170, a phase retardation layer 180, and a heat dissipation substrate 190. In FIG. 2, the thin film transistor TFT, the organic light emitting display device 130, the encapsulation layer 140, and the touch sensor part 150 are illustrated as a display part DP for convenience of description.

As shown in FIG. 1, the glass substrate 110 comprises a display area DA and a non-display area NDA. The display area DA is an area where a plurality of pixels is disposed and an image is substantially displayed. In the display area DA, a display element displaying an image, and a variety of driving elements for driving the display element may be disposed.

The thickness of the glass substrate 110 may be from 30 μm to 200 μm. In the case where the thickness of the glass substrate 110 is within the above range, the glass substrate 110 may support components of the organic light emitting display device 100, and at the same time, a fold or a bend of the display device may be embodied. Specifically, the glass substrate 110 may be formed in such a way to etch a mother glass substrate of thickness from 400 μm to 800 μm or from 500 μm to 650 μm. That is, the mother glass substrate has an enough thickness to withstand conditions and environments for manufacturing. However, since a display panel is consecutively formed on the mother glass substrate, the lower surface of the mother glass substrate may be damaged during manufacturing. To prevent this from happening, the surface properties of the mother glass substrate need to improve. To this end, the outer surface of the mother glass substrate may be uniformized while the thickness of the mother glass substrate decreases in an etching process.

A plurality of pixels may be included in the display area DA. The plurality of pixels is arranged in a matrix form, and each of the plurality of pixels may comprise a plurality of sub pixels SP. Each of the sub pixels SP, as a component for displaying one color, may be defined as an area where a plurality of gate lines disposed in a first direction, and a plurality of data lines disposed in a second direction different from the first direction cross each other. Herein, the first direction may be a horizontal direction (an X-axis direction) of FIG. 1, and the second direction may be a vertical direction (a Y-axis direction) of FIG. 1, but not limited thereto. Each of the sub pixels SP comprises a light emitting area where light is emitted, and a non-light emitting area where light is not emitted, but in the present disclosure, the area where light is emitted is only defined as a sub pixel SP. Each of the plurality of pixels may comprise a first sub pixel SP1, a second sub pixel SP2 and a third sub pixel SP3. The first sub pixel SP1 may be a red pixel, the second sub pixel SP2 may be a green pixel, and the third sub pixel SP3 may be a blue pixel, but not limited thereto.

Each of the sub pixels SP may comprise an organic light emitting element 130 and a driving element. The driving element may comprise a switching transistor, a driving transistor and the like. The driving element may electrically connect signal lines such as a gate line, a data line and the like connecting to a gate driver, a data driver and the like that are disposed in the non-display area NDA.

The non-display area NDA may be disposed in a surrounding area of the glass substrate 110, and may be an area where an image is not displayed. The non-display area NDA may be disposed to surround the display area DA. In the non-display area NDA, a variety of components for driving the plurality of sub pixels SP disposed in the display area DA may be disposed. For example, in the non-display area NDA, a driving IC providing a signal for driving the plurality of sub pixels SP, a driving circuit, a signal line, a flexible film and the like may be disposed. The driving IC may comprise a gate driver, a data driver and the like. The driving IC and the driving circuit may be disposed based on a gate in panel (GIP) method, a chip on film (COF) method, a tape automated bonding (TAB) method, a tape carrier package (TCP) method, a chip on glass (COG) method and the like.

As shown in FIG. 3 together, a first buffer layer 121 for preventing the infiltration of oxygen or moisture may be disposed on the glass substrate 110. The first buffer layer 121 may have a single-layered structure, and when necessary, have a multi-layered structure.

The thin film transistor TFT comprising a gate electrode G, an active layer ACT, a source electrode S and a drain electrode D is disposed on the first buffer layer 121. The thin film transistor FTF is disposed in each of the first sub pixel SP1 area, the second sub pixel SP2 area and the third sub pixel area SP3. In FIG. 3, a driving thin film transistor is only illustrated for convenience of description, among a variety of thin film transistors that may be included in the organic light emitting display device 100. Additionally, in FIG. 3, the thin film transistor TFT has a coplanar structure, for example, but not be limited thereto, and may also have an inverted staggered structure.

For example, the active layer ACT is disposed on the first buffer layer 121, and a gate insulation layer 123 for insulating the active layer ACT and the gate electrode G is disposed on the active layer ACT. Additionally, an interlayer insulation layer 122 for insulating the gate electrode G, the source electrode S and the drain electrode D is disposed on the first buffer layer 121. The source electrode S and the drain electrode D respectively contacting the active layer ACT are formed on the interlayer insulation layer 122. A planarization layer 124 may be disposed on the thin film transistor TFT. The planarization layer 124 planarizes the upper portion of the thin film transistor TFT. The planarization layer 124 may comprise a contact hole for electrically connecting the thin film transistor TFT and an anode 131 of the organic light emitting element 130.

The organic light emitting element 130 is disposed on the planarization layer 124. The organic light emitting element 130 comprises a first organic light emitting element 130a disposed in the first sub pixel SP1, a second organic light emitting element 130b disposed in the second sub pixel SP2, and a third organic light emitting element 130c disposed in the third sub pixel SP3. Each of the organic light emitting elements 130a, 130b, 130c comprises an anode 131, an organic light emitting layer 132 and a cathode 133.

The anode 131 is disposed on the planarization layer 124. The anode 131 is disposed in such a way that the anode 131 corresponds to each of the plurality of sub pixels SP1, SP2, SP3. The anode 131 is formed of a conductive material of high work function, as a component for providing holes to the organic light emitting layer 132. The anode 131 may be a transparent conductive layer formed of transparent conductive oxide (TCO). For example, the anode 131 may be formed of one or more sorts selected from transparent conductive oxides such as indium-tin-oxide (ITO), indium-zinc-oxide (IZO), indium-tin-zinc oxide (ITZO), SnO2, ZnO, indium-copper-oxide (ICO) and Al:ZnO (AZO), but not limited thereto. In the case where the organic light emitting display device 100 is driven based on a top emission method, the anode 131 may further comprise a reflective layer for reflecting light emitted from the organic light emitting layer 132 toward the cathode 133. The anode 131 may be formed in such a way that the anode 131 separates for each of the first sub pixel SP1, the second sub pixel SP2 and the third sub pixel SP3.

A bank 125 is disposed on the anode 131 and the planarization layer 124. The bank 125 may cover the edge of the anode 131 of the organic light emitting element 130 and define a light emitting area. That is, the bank 125 may partition the plurality of sub pixels SP1, SP2, SP3. The bank 125 may be made of an insulation material to insulate the anodes 131 of adjacent sub pixels SP1, SP2, SP3 from one another. Additionally, the bank 125 may be comprised of a black bank having a high optical absorption rate to prevent a color mixture among the adjacent sub pixels SP1, SP2, SP3. For example, the bank 125 may be made of polyimide resin, acryl resin or benzocyclobutene resin, but not limited thereto.

The cathode 133 is disposed on the anode 131. The cathode 133 may be formed of a metallic material of low work function to smoothly provide electrons to the organic light emitting layer 132. For example, the cathode 133 may be formed of a metallic material selected from calcium (Ca), barium (Ba), aluminum (Al), silver (Ag) and an alloy comprising one or more sorts thereof, but not limited thereto. Additionally, the cathode 133 may be formed on the anode 131, in a single layer. That is, the cathode 133 may be formed in the first sub pixel SP1, the second sub pixel SP2 and the third sub pixel SP3, in a single layer. In the case where the organic light emitting display device 100 is driven based on the top emission method, the cathode 133 is formed to be very thin so that the cathode 133 may become transparent substantially.

The organic light emitting layer 132 is disposed between the anode 131 and the cathode 133. The organic light emitting layer 132 is a layer in which an electron and a hole are coupled to emit light. The organic light emitting layer of the first organic light emitting element 130a may be a green organic light emitting layer, the organic light emitting layer of the second organic light emitting element 130b may be a red organic light emitting layer, and the organic light emitting layer of the third organic light emitting element 130c may be a blue organic light emitting layer.

To enhance the light emission efficiency of the organic light emitting element 130, the organic light emitting element 130 may further comprise a hole injection layer, a hole transport layer, an electron transport layer, an electron injection layer and the like. For example, the hole injection layer and the hole transport layer may be disposed between the anode 131 and the organic light emitting layer 132, and the electron transport layer and the electron injection layer may be disposed between the organic light emitting layer 132 and the cathode 133. Additionally, to enhance the re-coupling efficiency of the hole and the electron further in the organic light emitting layer 132, the organic light emitting layer 132 further comprise a hole blocking layer or an electron blocking layer.

The encapsulation layer 140 is disposed on the organic light emitting element 130. The encapsulation layer 140 may cover the organic light emitting element 130. The encapsulation layer 140 may protect the organic light emitting element 130 from external moisture, external oxygen, external impacts and the like. The encapsulation layer 140 may have a multi-layered structure in which an inorganic layer formed of an inorganic insulation material and an organic layer formed of an organic material are stacked. For example, the encapsulation layer 140 may be comprised of at least one organic layer and at least two inorganic layers, and may have a multi-layered structure in which an inorganic layer and an organic layer are stacked alternately, but may not be limited there to. The encapsulation layer 140, for example, may have a triple-layered structure in which a first inorganic layer 141, an organic layer 142 and a second inorganic layer 143 are included. At this time, each of the first inorganic layer 141 and the second inorganic layer 143 may be independently formed of one or more sorts selected from silicon nitride (SiNx), silicon oxide (SiOx), aluminum oxide (AlOx), silicon oxy nitride (SiON), but not limited thereto. Further, the organic layer 142 may be formed of one or more sorts selected from epoxy resin, polyimide, polyethylene, and silicon oxycarbide (SiOC), but not limited thereto.

To provide a touch sensing function to the organic light emitting display device 100, the touch sensor part 150 is disposed on the encapsulation layer 140. The organic light emitting display device 100 of one embodiment comprises a touch sensor part 150 having a structure in which a touch electrode 151 is formed on an encapsulation layer 140, rather than a structure in which an existing touch panel, where a touch electrode is formed on a separate substrate, is disposed on an organic light emitting element through an adhesive member. As the touch sensor part 150 is immediately formed on the encapsulation layer 140, an adhesive member for sticking the touch sensor part 150 and an organic light emitting display panel may be omitted so that the thickness of the organic light emitting display device 100 may become slim.

The touch sensor part 150 comprises a touch electrode 151 and a touch protective layer 152. The touch electrode 151 may be directly formed on the encapsulation layer 140 without an adhesive member. The touch electrode 151 as an electrode that senses a touch input may be comprised of a sensing electrode and a driving electrode, and may sense a change in the capacitance between the sensing electrode and the driving electrode and detect a touch coordinate. For example, the driving electrode may be disposed on the second inorganic layer 143, and the sensing electrode may be disposed on the same planar surface as the driving electrode. In another example, a touch insulation layer may be disposed on the driving electrode, and the sensing electrode may be disposed on the touch insulation layer. The disposition of the touch electrode 151 may not be limited to the above-described one, and when necessary, may vary.

Since the touch electrode 151 is formed directly on the encapsulation layer 140, a distance between the organic light emitting element 130 and the touch electrode 151 is so short that parasitic capacitance is generated between the electrode, included in the organic light emitting element 130 or the thin film transistor TFT, and the touch electrode 151, thereby causing a decrease in the touch sensitivity. To prevent this from happening, the thickness of the encapsulation layer 140 may be adjusted properly, to minimize parasitic capacitance.

The touch electrode 151 may be formed of a transparent metallic material capable of transmitting light such as indium-tin-oxide (ITO) or indium-zinc-oxide (IZO). The touch electrode 151 may have a variety of shapes such as a rectangle, an octagon, a circle or a rhombus.

The touch protective layer 152 is disposed on the touch electrode 151. The touch protective layer 152 prevents a short of the touch electrode 151, or damage to the touch electrode 151, and the like, and planarizes the upper surface of the touch electrode 151. The touch protective layer 152 may be formed of transparent insulation resin such as acryl-based resin, polyester-based resin, epoxy resin, silicon-based resin and the like.

Further, in FIG. 3, a structure in which the touch electrode 151 of the touch sensor part 150 is disposed on the encapsulation layer 140 in direct contact with the encapsulation layer 140 is illustrated, but not limited thereto. For example, a touch buffer layer may be disposed between the encapsulation layer 140 and the touch sensor part 150, and the touch electrode 151 may be disposed on the touch buffer layer. The touch buffer layer may prevent damage to the encapsulation layer 140 and the organic light emitting element 130 in the process where the touch electrode 151 is directly formed on the encapsulation layer 140.

The touch buffer layer may be formed of an inorganic material having excellent barrier properties. Accordingly, the touch buffer layer may minimize the infiltration of moisture or oxygen. The touch buffer layer, for example, may be made of an inorganic material such as silicon nitride (SiNx), silicon oxide (SiOx), aluminum oxide (AlOx) and the like, but not limited thereto.

The polarization layer 160 may be disposed on the touch sensor part 150. The polarization layer 160 as a layer for polarizing input light may comprise a polarization plate POL that prevents deterioration in contrast ratios by absorbing external light and reflected light thereof as a film having a predetermined level of light transmittance. That is, deterioration in the display quality, caused by reflected light where external light is reflected, may be prevented, and the transmittance of an image of the display device may improve. Since the polarization plate POL is disposed in the display area DA, the size of the polarization plate POL may be less than the size of the glass substrate 110, and specifically, four edges of the polarization plate POL may be disposed inside four edges of the glass substrate 110.

A first adhesive layer OCA1 may be disposed between the touch sensor part 150 and the polarization layer 160. The first adhesive layer OCA1 may use an optical clear adhesive (OCA) to minimize the generation of bubbles or foreign substances between the touch sensor part 150 and the polarization layer 160.

The cover glass 170 may be disposed on the polarization layer 160. The cover glass 170 may protect the display panel from external impacts, external moisture, external heat and the like. For example, the cover glass 170 may be tempered glass of high Young's modulus, but not limited thereto.

A second adhesive layer OCA2 may be disposed between the polarization layer 160 and the cover glass 170. Like the first adhesive layer OCA1, the second adhesive layer OCA2 may use an optical clear adhesive (OCA) to minimize the generation of bubbles or foreign substances between the polarization layer 160 and the cover glass 170.

Hereinafter, the phase retardation layer 180 disposed under the glass substrate 110 is described specifically, with reference to FIG. 2. In FIG. 2, the thin film transistor TFT, the organic light emitting element 130, the encapsulation layer 140, and the touch sensor part 150 are illustrated as a display part DP for convenience of description.

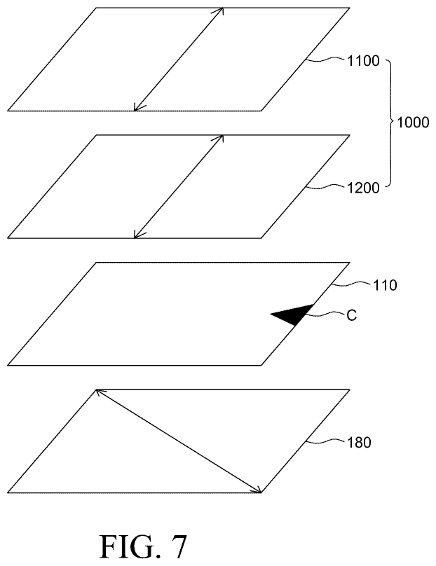

As shown in FIG. 2, the phase retardation layer 180 comprising a phase retardation film having an in-plane retardation value Ro from 120 nm to 300 nm may be disposed under the glass substrate 110. The phase retardation film may compensate a retardation of light passing through a portion of the glass substrate 110, where a crack C is created, and ensure ease of detection of the crack C. Specifically, the optic axis of the phase retardation film may be 45° or 135° with respect to the long axis or the short axis of the glass substrate. This is because the polarization axis of a crack detector is ordinarily parallel with the long axis or the short axis of the glass substrate 110, and detailed description in relation to this is provided hereinafter with reference to FIG. 7. Further, to prevent chromatic aberration, a thickness retardation value Rth of the phase retardation film may be less than an in-plane retardation value Ro of the phase retardation film. At this time, a retardation delay value of the phase retardation film may be λ/4 or λ/2.

Ordinarily, the glass substrate may have a crack due to an external impact during manufacturing, and moisture may infiltrate through the crack, causing a failure to the display device. To prevent this from happening, a TFT tester or a tester comprising a polarization member and a reflection plate may be used to detect a crack of the glass substrate. In the case of a TFT tester comprising a liquid crystal layer, voltage may be supplied to a TFT and lines, and the liquid crystal layer of the TFT tester may be driven by the voltage, to test a failure of the TFT and the lines. However, it is difficult to detect a crack created at an outer portion of the panel, having no lines, i.e., in the non-display area and to detect a crack created after the TFT processing.

Further, in the case of a tester comprising a polarization member and a reflection plate, a failure may be detected in such a way that a camera recognizes a difference in colors caused by the retardation of a light source reflected from a portion where a crack is created and from a portion where a crack is not created. However, in the case where the size of a crack is from a few μm to dozens of μm, that is, the size of a crack is so minute, there is a slight different in refractive indices, making it hard to recognize a change in colors and detect a failure.

Additionally, there are times when a minute crack is created easily by an external impact in the process where the mother glass substrate is etched to make the mother glass substrate thin, and to prevent the glass substrate from an external impact, polyurethane foam may be disposed under the glass substrate. However, there are pores in polyurethane foam, and through the pores, light is likely to be scattered, causing an increase in a thickness retardation Rth in the process where a crack is detected and the generation of chromatic aberration.

Accordingly, in the organic light emitting display device 100 of one embodiment, the phase retardation layer 180 is disposed under the glass substrate 110, so that the retardation of a light source transmitted through or reflected from a portion where a crack C is created is compensated, making it possible to detect the crack C. That is, the organic light emitting display device 100 of one embodiment may prevent the creation of a crack C on the glass substrate 110, thereby enhancing reliability.

A third adhesive layer OCA3 may be disposed between the glass substrate 110 and the phase retardation layer 180. Like the first adhesive layer OCA1, the third adhesive layer OCA3 may use an optically clear adhesive (OCA) to minimize the generation of bubbles or foreign substances between the glass substrate 110 and the phase retardation layer 180. At this time, to minimize a change in retardations caused by the third adhesive layer OCA3, the third adhesive layer OCA3 may be made of a material having the same refractive index as the glass substrate 110 in the process where a crack C is detected. Additionally, the refractive index and retardation of the phase retardation film may decrease at glass transition temperature Tg or greater, or the refractive index of the third adhesive layer OCA3 may decrease at glass transition temperature Tg or greater. Accordingly, to minimize a change in optical properties, caused by a change in temperatures, the glass transition temperature Tg of the third adhesive layer OCA3 may be greater than the glass transition temperature Tg of the phase retardation film. Specifically, the glass transition temperature Tg of the phase retardation film may be 90° C. or greater, and the glass transition temperature Tg of the third adhesive layer OCA3 may be 150° C. or greater. Further, to minimize deformation caused by a difference between the physical properties of the glass substrate 110 and the third adhesive layer OCA3, the storage modulus of the third adhesive layer OCA3 may be 10⁶ Pa or greater, but not limited thereto.

The heat dissipation substrate 190 may be disposed under the glass substrate 110. The heat dissipation substrate 190 may be made of a material having excellent heat conductivity, and for example, made of aluminum (Al) but not limited thereto.

A fourth adhesive layer OCA4 may be disposed between the phase retardation layer 180 and the heat dissipation substrate 190. Like the first adhesive layer OCA1, the fourth adhesive layer OCA4 may use an optically clear adhesive OCA to minimize the generation of bubbles or foreign substances between the phase retardation layer 180 and the heat dissipation substrate 190.

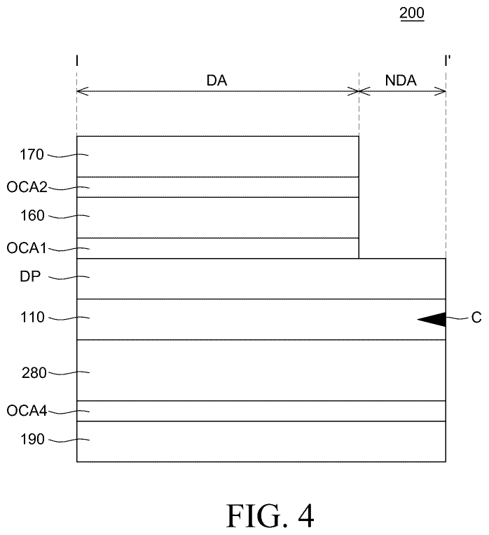

Hereinafter, an organic light emitting display device 200 of another embodiment is specifically described with reference to FIG. 4.

FIG. 4 is a cross-sectional view of on organic light emitting display device of another embodiment. The components of the organic light emitting display device 200 of FIG. 4 are substantially the same as the components of the organic light emitting display device 100 of FIGS. 1-3, except for the configuration of a phase retardation layer 280 and the presence or absence of a third adhesive layer OCA3, and accordingly, the common components are not described.

As shown in FIG. 4, a phase retardation layer 280 comprising a liquid crystal-coated layer having an in-plane retardation value Ro from 120 nm to 300 nm may be disposed under the glass substrate 110. The liquid crystal-coated layer may compensate the retardation of light passing through a portion of the glass substrate 110 where a crack C is created, to ensure ease of detection of the crack C. Specifically, the optic axis of the liquid crystal-coated layer may be 45° or 135° with respect to the long axis or the short axis of the glass substrate. This is because the polarization axis of a crack detection device is ordinarily parallel with the long axis or the short axis of the glass substrate 110, and detailed description in relation to this is provided hereinafter with reference to FIG. 7. Additionally, to prevent color characteristic distortion depending on a viewing angle, a thickness retardation value Rth of the liquid crystal-coated layer may be less than an in-plane retardation value Ro of the liquid crystal-coated layer. Further, a retardation delay value of the liquid crystal-coated layer may be λ/4 or λ/2. In the case where the phase retardation layer 280 comprises a liquid crystal-coated layer, the liquid crystal-coated layer may be disposed in such a way that the liquid crystal-coated layer directly contacts the lower surface of the glass substrate 110 without a separate adhesive layer.

In the organic light emitting display device 200 of another embodiment, the phase retardation layer 280 is disposed under the glass substrate 110, to compensate the retardation of a light source transmitted through or reflected from a portion where a crack C is created, making it possible to detect the crack C. That is, the organic light emitting display device 200 of another embodiment prevents the creation of a crack C on the glass substrate 110, thereby ensuring improvement in reliability.

Additionally, in the organic light emitting display device 200 of another embodiment, the phase retardation layer 280 is disposed in such a way that the phase retardation layer 280 directly contacts the lower surface of the glass substrate 110, thereby reducing the thickness of the organic light emitting display device 200.

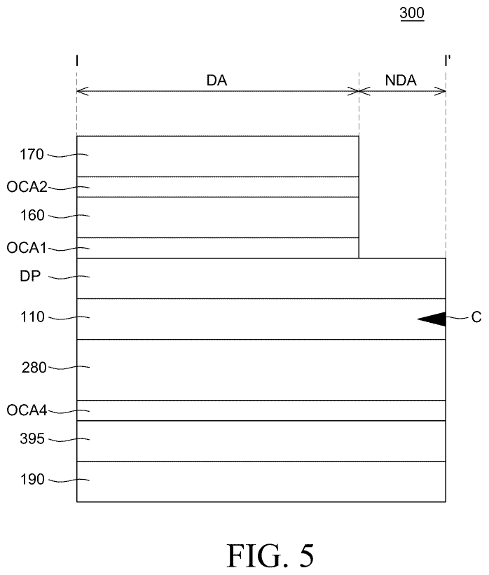

FIG. 5 is a cross-sectional view of an organic light emitting display device of another embodiment. The components of an organic light emitting display device 300 of FIG. 5 are substantially the same as the components of the organic light emitting display device 200 of FIG. 4, except for the presence or absence of a protective film 395, and accordingly, the common components are not described.

As shown in FIG. 5, the protective film 395 may be disposed on the lower surface of the phase retardation layer 280. The protective film 395 may prevent a crack C by reducing an impact during manufacturing. At this time, unlike the phase retardation layer 280, the protective film 395 may have an in-plane retardation value Ro of 0 to minimize a change in retardations caused by the protective film 395 while a crack C is detected. For example, the protective film 395 may be formed of a tri-acetyl cellulose (TAC) film, but not limited thereto.

In the organic light emitting display device 300 of another embodiment, the phase retardation layer 280 is disposed under the glass substrate 110, to compensate the retardation of a portion where a crack C is created, making it possible to detect the crack C. That is, the organic light emitting display device 300 of another embodiment may prevent the generation of a crack C on the glass substrate 110, ensuring improvement in reliability.

Additionally, in the organic light emitting display device 300 of another embodiment, the phase retardation layer 280 is disposed in such a way that the phase retardation layer 280 directly contacts the lower surface of the glass substrate 110, reducing the thickness of the organic light emitting display device 300.

Further, in the organic light emitting display device 300 of another embodiment, the protective film 395 is disposed under the glass substrate 100, thereby preventing the generation of a crack C of the glass substrate 110 more effectively.

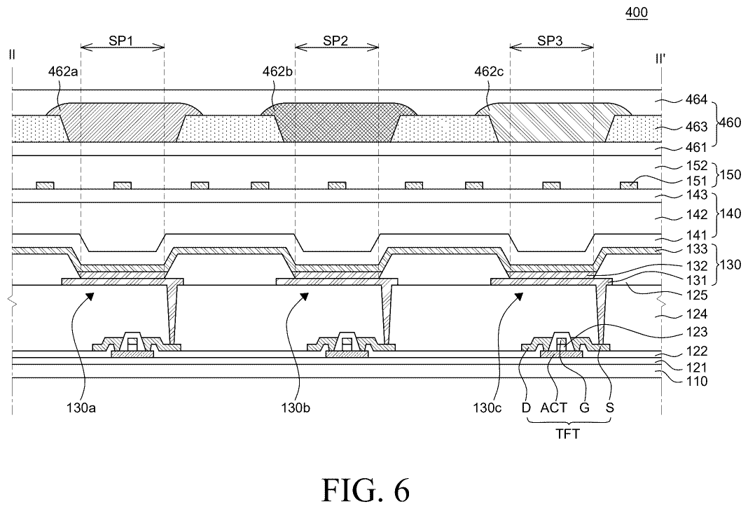

FIG. 6 is a cross-sectional view of an organic light emitting display device of yet another embodiment. The components of the organic light emitting display device 400 of FIG. 6 are substantially the same as the components of the organic light emitting display device 100 of FIGS. 1-3 except for a polarization layer 460, and accordingly, the common components are not described.

As shown in FIG. 6, a second buffer layer 461 may be disposed on the touch sensor part 150. The second buffer layer 461 may protect the components of the organic light emitting display device 400 by preventing the infiltration of moisture or oxygen from the outside. The second buffer layer 461 may be formed of an inorganic material having excellent barrier properties. Accordingly, the infiltration of moisture or oxygen may be minimized. For example, the second buffer layer 461 may be formed of one or more sorts of inorganic materials selected from silicon nitride (SiNx), silicon oxide (SiOx), silicon oxynitride (SiON) or aluminum oxide (Al2O3), but not limited thereto. Additionally, the second buffer layer 461 may complement an adhesive force between a plurality of color filters 462a, 462b, 462c and a black matrix 463, and the touch protective layer 152. That is, the second buffer layer 461 may be disposed on the touch protective layer 152 to bond the plurality of color filters 462a, 462b, 462c and the black matrix 463 to the touch protective layer 152.

The polarization layer 460 comprising the plurality of color filters 462a, 462b, 462c and the black matrix 463 may be disposed on the second buffer layer 461. The plurality of color filters 462a, 462b, 462c and the black matrix 463 may absorb external light and function as an anti-reflection layer minimizing deterioration in the visibility and contrast ratio of the organic light emitting display device 400, caused by the external light.

The black matrix 463 is disposed on the encapsulation layer 140. The black matrix 463 may be disposed on the touch sensor part 150 or the buffer layer 461. The black matrix 463 is disposed along the boundary of a sub pixel, and comprises an opening exposing a sub pixel. The black matrix 463 partitions each of the plurality of color filters 462a, 462b, 462c. The black matrix 463 may be disposed to overlap the bank 125. Accordingly, a mixture of colors among the sub pixels SP1, SP2, SP3 may be minimized. Further, the black matrix 463 may absorb external light. Thus, deterioration in the visibility and contrast ratio of the organic light emitting display device (400), caused by external light, may be minimized.

The black matrix 463 may be formed of an organic material. The black matrix 463 comprises a base resin and a black material. The base resin may be one or more sorts selected from carbon-based resin, epoxy-based resin, acrylate-based resin, siloxane-based resin, and polyimide, but not limited thereto. The black material may be black pigment selected from carbon-based pigment, metal oxide-based pigment, and organic pigment. For example, the carbon-based pigment may be carbon black. For example, the metal oxide-based pigment may be titan black (TiNxOy), Cu—Mn—Fe-based black pigment and the like, but not limited thereto. For example, the organic pigment may be selected from lactam black, perylene black, and aniline black but not limited thereto. Additionally, the black material may use RGB black pigment comprising red pigment, blue pigment and green pigment.

The plurality of color filters 462a, 462b, 462c is disposed on the encapsulation layer 140. The plurality of color filters 462a, 462b, 462c may be disposed on the touch sensor part 150 or the buffer layer 461. Additionally, the plurality of color filters 462a, 462b, 462c may be disposed to directly contact the buffer layer 461, and to cover a partial area of the black matrix 463. The plurality of color filters 462a, 462b, 462c absorbs external light and minimizes deterioration in the visibility and contrast ratio caused by the external light, thereby ensuring improvement in color reproduction. The plurality of color filters 462a, 462b, 462c is disposed on the encapsulation layer 140, so that light emission efficiency improves while the polarization plate POL is omitted.

The plurality of color filters 462a, 462b, 462c may be disposed to correspond to sub pixels disposed thereunder. At this time, each of the color filters 462a, 462b, 462c may correspond to a color of each of the sub pixels corresponding thereto. That is, the plurality of color filters 462a, 462b, 462c comprises a first color filter 462a corresponding to the first sub pixel SP1, a second color filter 462b corresponding to the second sub pixel SP2, and a third color filter 462c corresponding to the third sub pixel SP3.

Each of the color filters 462a, 462b, 462c comprises a transparent base resin and a coloring substance. For example, the transparent base resin may be one sort selected from polyacrylate, polymethacrylate, polyimide, polyvinyl alcohol, polyethylene, polypropylene, polystyrene, polyethylene terephthalate, and the like, but not limited thereto.

The plurality of color filters 462a, 462b, 462c and the black matrix 463 are disposed on the buffer layer 461. The plurality of color filters 462a, 462b, 462c and the black matrix 463 may be integrally formed on the same planar surface, and may absorb external light and minimize deterioration in the visibility and contrast ratio of the organic light emitting display device 400, caused by the external light.

An over coating layer 464 may be disposed on the plurality of color filters 462a, 462b, 462c and the black matrix 463. The over coating layer 464 may planarize the upper portions of the plurality of color filters 462a, 462b, 462c and the black matrix 463.

Hereinafter, a process of detecting a crack C created on the glass substrate 110 of the organic light emitting display device 100 of one embodiment is specifically described with reference to FIG. 7.

FIG. 7 is a schematic view of a process of detecting a crack of a glass substrate in the organic light emitting display device of one embodiment. In FIG. 7, the phase retardation layer 180 of the glass substrate 110 of the organic light emitting display device 100 is only illustrated, and a polarization member 1100 and a liquid crystal layer 1200 of a crack detector 1000 are only illustrated for convenience of description.

As shown in FIG. 7, the crack detector 1000 may comprise a polarization member 1100 and a liquid crystal layer 1200. The polarization member 1100 is a layer for polarizing light input thereto. The polarization member 1100 may be comprised of a plurality of layers to selectively transmit light, i.e., to polarize light.

The liquid crystal layer 1200 may be disposed under the polarization member 1100. The liquid crystal layer 1200 has anisotropy and polarization properties, and as voltage is supplied, the arrangement of liquid crystal molecules is adjusted in a predetermined direction. The liquid crystal layer 1200, for example, may be driven in a polymer dispersed liquid crystal (PDLC) mode or a twisted nematic (TN) mode.

The optic axes of the polarization member 1100 and the liquid crystal layer 1200 may form an angle from 45° to 135° with the optic axis of the phase retardation layer 180. For example, in the case where the crack detector 1000 is in a transmittance mode, the phase retardation layer 180 may have a retardation delay value of λ/2. That is, the phase of a light source passing through a portion where a crack C is created is delayed by λ/2, and the crack C may be easily detected although the crack C has a minute size.

Though not illustrated in the drawings, in the case where a reflection plate is additionally disposed under the organic light emitting display device 100, the phase retardation layer 180 may have a retardation delay value of λ, and a λ delay is carried out as external light is input, and a λ delay is carried out as the external light is reflected from the reflection plate, so that a phase delay is carried out by λ. That is, the phase of a light source passing through a portion where a crack C is created is delayed by λ/2, so that the crack C is detected easily although the crack C has a minute size.

Various example embodiments of the present disclosure can also be described as follows:

According to an aspect of the present disclosure, there is provided an organic light emitting display device. The organic light emitting display device comprises a glass substrate; an organic light emitting element on the glass substrate; and a phase retardation layer disposed under the glass substrate.

An in-plane retardation value (Ro) of the phase retardation layer may be from 120 nm to 300 nm.

A thickness retardation value (Rth) of the phase retardation layer may be less than the in-plane retardation value (Ro) of the phase retardation layer.

The phase retardation layer may be a retardation layer of λ/4 or λ/2.

An optic axis of the phase retardation layer may be 45° or 135° with respect to a long axis or a short axis of the glass substrate.

The phase retardation layer may comprise a phase retardation film.

The organic light emitting display device may further comprise an adhesive layer disposed between the phase retardation film and the glass substrate.

The adhesive layer may be formed of an optical clear adhesive.

A glass transition temperature (Tg) of the adhesive layer may be greater than a glass transition temperature (Tg) of the phase retardation film.

A refractive index of the adhesive layer may be the same as a refractive index of the glass substrate.

A storage modulus of the adhesive layer may be 10⁶ Pa or greater.

The phase retardation layer may comprise a liquid crystal-coated layer.

The liquid crystal-coated layer may be disposed to directly contact a lower surface of the glass substrate.

The organic light emitting display device may further comprise a protective film disposed on a lower surface of the liquid crystal-coated layer, and configured to have an in-plane retardation value (Ro) of 0.

The organic light emitting display device may further comprise a polarization layer disposed on the organic light emitting element.

The polarization layer may comprise a polarization plate, and a size of the polarization plate may be less than a size of the glass substrate, and four edges of the polarization plate may be placed inside four edges of the glass substrate.

The organic light emitting display device may further comprise an encapsulation layer configured to cover the organic light emitting element, and the polarization layer may be comprised of a plurality of color filters disposed on the encapsulation layer to correspond to a plurality of sub pixels and a black matrix disposed between the plurality of color filters.

A thickness of the glass substrate may be from 30 μm to 200 μm.

The glass substrate may comprise a display area and a non-display area, and a crack having a size of from 3 μm to 100 μm may be formed in the non-display area.

The organic light emitting display device may further comprise a heat dissipation substrate disposed under the phase retardation layer.

It will be apparent to those skilled in the art that the present disclosure is not limited by the above-described example embodiments and the accompanying drawings, and that various substitutions, modifications, and variations can be made in the present disclosure without departing from the spirit or scope of the disclosures. Therefore, the above example embodiments of the present disclosure are provided for illustrative purposes and are not intended to limit the scope or technical concept of the present disclosure. The protective scope of the present disclosure should be construed based on the following claims and their equivalents, and it is intended that the present disclosure cover all modifications and variations of this disclosure that come within the scope of the claims and their equivalents.

What is claimed is:

1. An organic light emitting display device, comprising:
a glass substrate;
an organic light emitting element on the glass substrate; and
a phase retardation layer disposed under the glass substrate.

2. The organic light emitting display device of claim 1, wherein an in-plane retardation value (Ro) of the phase retardation layer is in a range from 120 nm to 300 nm.

3. The organic light emitting display device of claim 2, wherein a thickness retardation value (Rth) of the phase retardation layer is less than the in-plane retardation value (Ro) of the phase retardation layer.

4. The organic light emitting display device of claim 2, wherein the phase retardation layer is a retardation layer of λ/4 or λ/2.

5. The organic light emitting display device of claim 2, wherein an optic axis of the phase retardation layer is 45° or 135° with respect to a long axis or a short axis of the glass substrate.

6. The organic light emitting display device of claim 1, wherein the phase retardation layer comprises a phase retardation film.

7. The organic light emitting display device of claim 6, further comprising an adhesive layer disposed between the phase retardation film and the glass substrate.

8. The organic light emitting display device of claim 7, wherein the adhesive layer is formed of an optical clear adhesive.

9. The organic light emitting display device of claim 7, wherein a glass transition temperature (Tg) of the adhesive layer is greater than a glass transition temperature (Tg) of the phase retardation film.

10. The organic light emitting display device of claim 7, wherein a refractive index of the adhesive layer is the same as a refractive index of the glass substrate.

11. The organic light emitting display device of claim 7, wherein a storage modulus of the adhesive layer is 10⁶ Pa or greater.

12. The organic light emitting display device of claim 1, wherein the phase retardation layer comprises a liquid crystal-coated layer.

13. The organic light emitting display device of claim 12, wherein the liquid crystal-coated layer is disposed to directly contact a lower surface of the glass substrate.

14. The organic light emitting display device of claim 12, further comprising a protective film disposed on a lower surface of the liquid crystal-coated layer and configured to have an in-plane retardation value (Ro) of 0.

15. The organic light emitting display device of claim 1, further comprising a polarization layer disposed on the organic light emitting element.

16. The organic light emitting display device of claim 15, wherein:
the polarization layer comprises a polarization plate; and
a size of the polarization plate is less than a size of the glass substrate, and four edges of the polarization plate are placed inside four edges of the glass substrate.

17. The organic light emitting display device of claim 15, wherein:
the organic light emitting display device further comprises an encapsulation layer configured to cover the organic light emitting element; and
the polarization layer is comprised of a plurality of color filters disposed on the encapsulation layer to correspond to a plurality of sub pixels and a black matrix disposed between the plurality of color filters.

18. The organic light emitting display device of claim 1, wherein a thickness of the glass substrate is in a range from 30 μm to 200 μm.

19. The organic light emitting display device of claim 1, wherein:
the glass substrate comprises a display area and a non-display area; and
a crack having a size in a range from 3 μm to 100 μm is formed in the non-display area.

20. The organic light emitting display device of claim 1, further comprising a heat dissipation substrate disposed under the phase retardation layer.

21. The organic light emitting display device of claim 9, wherein the glass transition temperature of the adhesive layer is 150° C. or greater, and the glass transition temperature of the phase retardation film is 90° C. or greater.

22. The organic light emitting display device of claim 9, wherein the phase retardation layer compensates a retardation of a light source transmitted through or reflected from a portion of the glass substrate where a crack is created.

23. A method of detecting a crack of a glass substrate in the organic light emitting display device according to claim 1, the method comprising:
detecting the crack of the glass substrate by using a crack detector,
wherein the crack detector comprises a polarization member and a liquid crystal layer disposed under the polarization member, and optic axes of the polarization member and the liquid crystal layer form an angle from 45° to 135° with an optic axis of a phase retardation layer of the organic light emitting display device.
